(19) United States
(12) Patent Application Publication
(10) Pub. No.: US 2007/0251242 A1
(43) Pub. Date: Nov. 1, 2007

(54) Method and apparatus for thermoelectrically generating cool/warm air

(76) Inventor: Chin-Kuang Luo, Taichung City (TW)

Correspondence Address: TROP PRUNER & HU, PC, 1616 S. VOSS ROAD, SUITE 750, HOUSTON, TX, 77057-2631, US

(21) Appl. No.: 11/637,549

(22) Filed: Dec. 12, 2006

(30) Foreign Application Priority Data
Apr. 26, 2006 (TW) 095114908

(51) Int. Cl. F25B 21/02; H01L 35/28

(52) U.S. Cl. 62/3.3; 136/204; 62/3.7

(57) ABSTRACT

An apparatus for thermoelectrically generating cool/warm air includes a heat collecting device, a thermoelectric generator device connected to the heat collecting device and capable of converting heat energy to electric energy, a thermoelectric cooling unit powered by electricity outputted from the thermoelectric generator device, a water storage unit connected to one side of the thermoelectric cooling unit, a temperature regulating unit, and a control unit. The temperature regulating unit includes a fan and a honeycomb type water screen connected to the water storage unit. When the control unit effects a rise or drop in temperature of the side of the thermoelectric cooling unit so that water in the water storage unit becomes hot or cold, by distributing the hot or cold water across the water screen and by operating the fan to generate an air current, a supply of warm or cool air can be quickly obtained.

### CROSS-REFERENCE TO RELATED APPLICATION

This application claims priority of Taiwanese Application No. 095114908, filed on Apr. 26, 2006.

### BACKGROUND OF THE INVENTION

1. Field of the Invention

The invention relates to a method and apparatus for generating cool/warm air, more particularly to a method and apparatus for thermoelectrically generating cool/warm air, which utilize electric energy outputted from a thermoelectric element.

2. Description of the Related Art

With drastic changes in weather around the world, use of cool/warm air generating apparatuses has become very popular. It is therefore desirable to have a cool/warm air generating apparatus that is highly efficient, that can save energy resources, and that is economical.

### SUMMARY OF THE INVENTION

Therefore, an object of the present invention is to provide an apparatus for thermoelectrically generating cool/warm air in a quick and effective manner. The apparatus can make use of an energy source other than the municipal electricity through thermoelectric conversion.

Another object of the present invention is to provide a method for thermoelectrically generating cool/warm air.

Accordingly, the apparatus for thermoelectrically generating cool/warm air of the present invention includes a heat collecting device, a thermoelectric generator device, a thermoelectric cooling unit, a water storage unit, a temperature regulating unit, and a control unit.

The heat collecting device includes a heat collecting portion for collecting heat energy, and a heat conducting portion connected to the heat collecting portion and capable of conducting the heat energy.

The thermoelectric generator device is provided on the heat conducting portion of the heat collecting device. The thermoelectric generator device is disposed to receive the heat energy for conversion into an electric energy output.

The thermoelectric cooling unit is disposed to receive the electric energy outputted from the thermoelectric generator device, and includes a first temperature face and a second temperature face opposite to the first temperature face.

The water storage unit includes a water tank connected to the first temperature face.

The temperature regulating unit includes, in sequence of arrangement, a fan, a honeycomb type water screen, a moisture absorbing screen, and an air outlet. The honeycomb type water screen is in fluid communication with the water tank, and has a honeycomb surface corresponding to the fan and capable of evenly distributing water flowing therealong.

The control unit is connected electrically to the thermoelectric generator device and the fan.

Water in the water tank is heated when the control unit is operated to effect a rise in temperature of the first temperature face of the thermoelectric cooling unit. The hot water is distributed evenly across the honeycomb type water screen. The fan is operated to blow hot moist air around the honeycomb type water screen toward the moisture absorbing screen, which absorbs water moisture in the hot moist air to result in relatively dry warm air that is outputted through the air outlet.

On the other hand, the water in the water tank is cooled when the control unit is operated to effect a drop in the temperature of the first temperature face of the thermoelectric cooling unit. The cold water is distributed evenly across the honeycomb type water screen. The fan is operated to blow cold moist air around the honeycomb type water screen toward the moisture absorbing screen, which absorbs water moisture in the cold moist air to result in relatively dry cool air that is outputted through the air outlet.

The method for thermoelectrically generating cool/warm air of the present invention includes:

(A) collecting heat energy;

(B) converting the heat energy to an electric energy output;

(C) supplying the electric energy output in step (B) to a thermoelectric cooling unit;

(D) causing water in a water tank to reach a desired temperature through the thermoelectric cooling unit;

(E) causing the water in the water tank to be distributed across a honeycomb type water screen;

(F) blowing air toward the honeycomb type water screen so as to generate an air current with a desired temperature; and

(G) passing the air current through a moisture absorbing screen such that the air current has a lowered moisture content, thereby resulting in an output of cool/warm air.

### BRIEF DESCRIPTION OF THE DRAWINGS

Other features and advantages of the present invention will become apparent in the following detailed description of the preferred embodiment with reference to the accompanying drawings, of which:

FIG. 1 is a block diagram to illustrate a preferred embodiment of an apparatus for thermoelectrically generating cool/warm air according to the present invention; and

FIG. 2 is a schematic sectional view to illustrate a heat collecting device and a thermoelectric generator device of the preferred embodiment.

### DETAILED DESCRIPTION OF THE PREFERRED EMBODIMENT

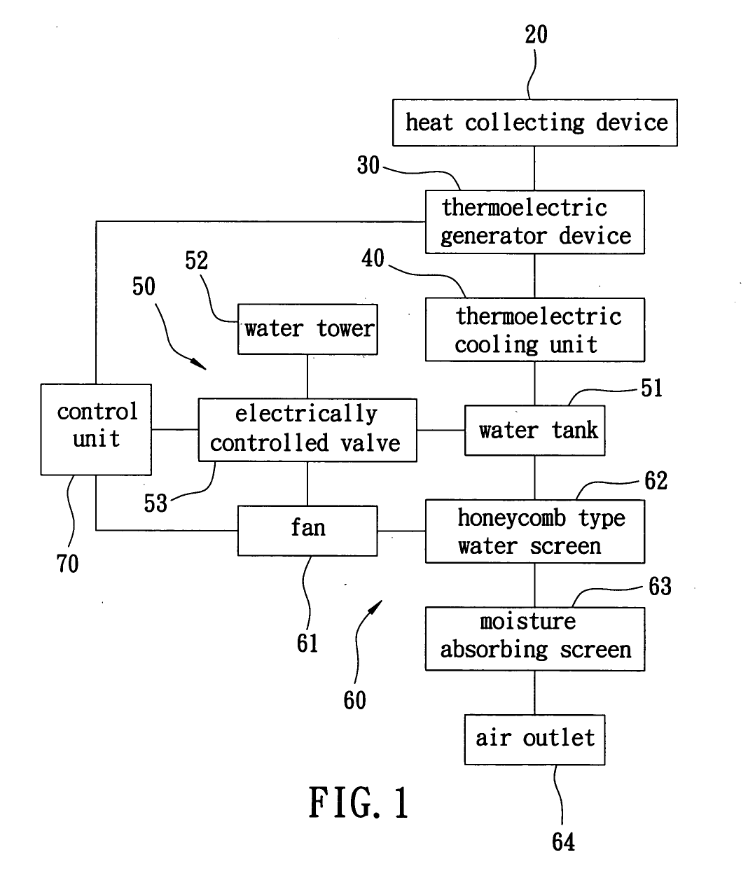

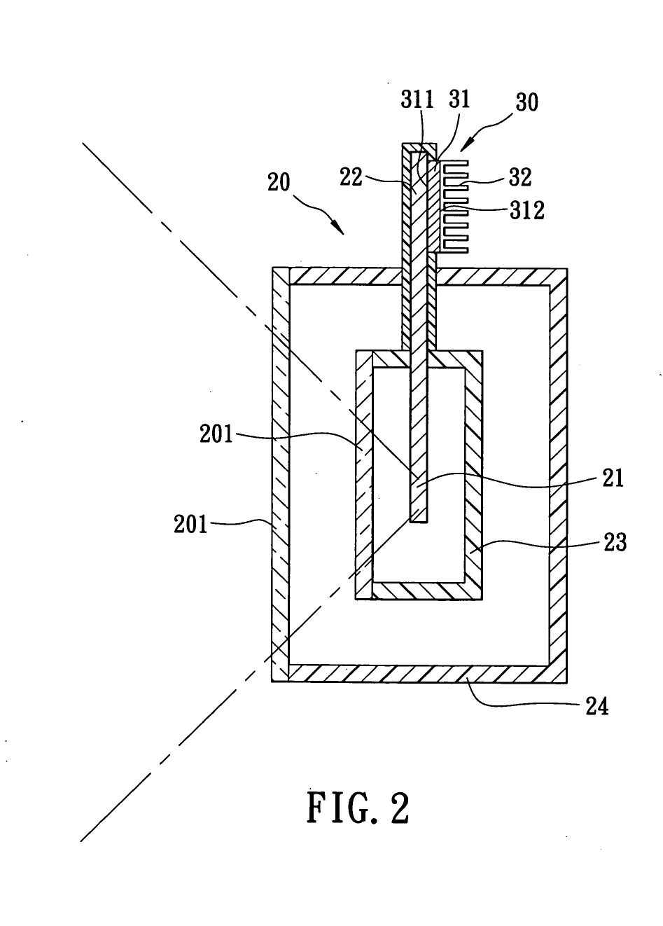

As shown in FIGS. 1 and 2, the preferred embodiment of an apparatus for thermoelectrically generating cool/warm air according to the present invention is shown to include a heat collecting device 20, a thermoelectric generator device 30, a thermoelectric cooling unit 40, a water storage unit 50, a temperature regulating unit 60, and a control unit 70.

The heat collecting device 20 includes a heat collecting portion 21, a heat conducting portion 22 connected to the heat collecting portion 21 and capable of conducting heat energy, a first vacuum device 23 surrounding the heat collecting portion 21, and a second vacuum device 24 surrounding the first vacuum device 23. Each of the first and second vacuum devices 23, 24 has a light-transmissive wall 201 corresponding to the heat collecting portion 21. The heat collecting device 20 is configured to collect solar energy in this embodiment, and can be configured to collect geothermal energy or heat generated during operation of a furnace in other embodiments of this invention. In this embodiment, the heat-transmissive wall 201 is disposed to face the sun so that solar heat energy can be collected in the heat collecting portion 21 and transferred to the heat conducting portion 22. A method for making the heat collecting device 20 is disclosed in the applicant's co-pending U.S. patent application Ser. No. 11/485,781, filed on Jul. 13, 2006.

The thermoelectric generator device 30 is provided on the heat conducting portion 22 of the heat collecting device 20, and is configured to receive heat energy for conversion to an electric energy output. The thermoelectric generator device 30 includes a thermoelectric element 31 and a heat-dissipating member 32. The thermoelectric element 31 has a heat-collecting side 311 in intimate contact with the heat conducting portion 22, and a heat-radiating side 312 opposite to the heat-collecting side 311 and in intimate contact with the heat-dissipating member 32. The thermoelectric element 31 in this embodiment is a highly efficient thermoelectric semiconductor device disclosed in the applicant's co-pending U.S. patent application Ser. No. 11/529,833, filed on Sep. 29, 2006, which has a highly-efficient thermoelectric converting function.

The thermoelectric cooling unit 40 is disposed to receive the electric energy outputted from the thermoelectric generator device 30, and includes a first temperature face (not shown) and a second temperature face (not shown) opposite to the first temperature face. The thermoelectric cooling unit 40 is also a highly efficient thermoelectric semiconductor device.

The water storage unit 50 includes a water tank 51 connected to the first temperature face, a water tower 52, and an electrically controlled valve 53 connected between the water tank 51 and the water tower 52. The electrically controlled valve 53 is disposed to control the amount of water flowing from the water tower 52 into the water tank 51.

The temperature regulating unit 60 includes, in sequence of arrangement, a fan 61, a honeycomb type water screen 62, a moisture absorbing screen 63, and an air outlet 64. The honeycomb type water screen 62 is in fluid communication with the water tank 51, and has a honeycomb surface (not shown) that is capable of evenly distributing the water currents. Both the honeycomb type water screen 62 and the moisture absorbing screen 63 are fabrics, and can be alternatively made from sponge, paper, etc.

The control unit 70 is connected electrically to the thermoelectric generator device 30, the electrically controlled valve 53, and the fan 61. In operation, the control unit 70 changes the polarities of the electricity (e.g., alternately changing the positive and negative polarities) supplied to the thermoelectric cooling unit 40 by the thermoelectric generator device 30 so as to achieve control of up- and down-adjustments of temperature of the first temperature face.

When the control unit 70 is operated to effect a rise in the temperature of the first temperature face of the thermoelectric cooling unit 40, water in the water tank 51 will be heated, and the hot water is distributed across the honeycomb type water screen 62 in trickles. At this time, the fan 61 is operated to blow the hot moist air around the honeycomb type water screen 62 toward the moisture absorbing screen 63. The moisture absorbing screen 63 absorbs the water moisture in the hot moist air to result in relatively dry warm air, which is then discharged through the air outlet 64. Thus, the function of providing warm air is achieved.

On the other hand, when the control unit 70 is operated to effect a drop in the temperature of the first temperature face of the thermoelectric cooling unit 40, the water in the water tank 51 will be cooled, and the cold water will be distributed across the honeycomb type water screen 62 in trickles. At this time, the fan 61 is operated to blow the cold moist air around the honeycomb type water screen 62 toward the moisture absorbing screen 63. The moisture absorbing screen 63 absorbs the water moisture in the cold moist air to result in relatively dry cool air, which is then discharged through the air outlet 64. Thus, the function of providing cool air is achieved.

Given the aforesaid, a method for thermoelectrically generating cool/warm air according to the present invention includes the following steps:

(A) collecting heat energy;

(B) converting the heat energy to an electric energy output;

(C) supplying the electric energy output in step (B) to the thermoelectric cooling unit 40;

(D) causing water in the water tank 51 to reach a desired temperature through the thermoelectric cooling unit 40 so as to generate cold/hot water;

(E) causing the water in the water tank 51 to be distributed across the honeycomb type water screen 62 in trickles;

(F) using the fan 61 to blow air toward the honeycomb type water screen 62 so as to generate an air current with a desired temperature; and

(G) passing the air current through the moisture absorbing screen 63 such that the air current has a lowered moisture content, thereby resulting in an output of cool/warm air.

From the foregoing, it can be appreciated that when the present invention is in operation, the heat collecting device 20 and the thermoelectric generator device 30 can cooperate to generate the electric energy required by the present invention. Besides, by distributing the cold/hot water that is generated through the thermoelectric cooling unit 40 across the honeycomb type water screen 62, the cold/hot moist air from the cold/hot water can be expanded in large areas. Finally, through the fan 61 and the moisture absorbing screen 63, the function of quickly generating cool/warm air can be achieved. Therefore, the present invention not only is highly efficient in generating cool/warm air, but also can utilize an energy source other than municipal electricity, thereby achieving power savings. Thus, the present invention not only is suitable for use in spacious environments, but is also power-saving and money-saving.

While the present invention has been described in connection with what is considered the most practical and preferred embodiment, it is understood that this invention is not limited to the disclosed embodiment but is intended to cover various arrangements included within the spirit and scope of the broadest interpretation so as to encompass all such modifications and equivalent arrangements.

I claim:

1. An apparatus for thermoelectrically generating cool/warm air, comprising:
a heat collecting device including a heat collecting portion for collecting heat energy, and a heat conducting portion connected to said heat collecting portion and capable of conducting the heat energy;
a thermoelectric generator device provided on said heat conducting portion of said heat collecting device, said thermoelectric generator device being disposed to receive the heat energy for conversion into an electric energy output;
a thermoelectric cooling unit disposed to receive the electric energy outputted from said thermoelectric generator device, and including a first temperature face and a second temperature face opposite to said first temperature face;
a water storage unit including a water tank connected to said first temperature face;
a temperature regulating unit including, in sequence of arrangement, a fan, a honeycomb type water screen, a moisture absorbing screen, and an air outlet, said honeycomb type water screen being in fluid communication with said water tank and having a honeycomb surface corresponding to said fan and capable of evenly distributing water flowing therealong; and
a control unit connected electrically to said thermoelectric generator device and said fan;
wherein water in said water tank is heated when said control unit is operated to effect a rise in temperature of said first temperature face of said thermoelectric cooling unit, the hot water being distributed evenly across said honeycomb type water screen, said fan being operated to blow hot moist air around said honeycomb type water screen toward said moisture absorbing screen, which absorbs water moisture in the hot moist air to result in relatively dry warm air that is outputted through said air outlet; and
wherein the water in said water tank is cooled when said control unit is operated to effect a drop in the temperature of said first temperature face of said thermoelectric cooling unit, the cold water being distributed evenly across said honeycomb type water screen, said fan being operated to blow cold moist air around said honeycomb type water screen toward said moisture absorbing screen, which absorbs water moisture in the cold moist air to result in relatively dry cool air that is outputted through said air outlet.

2. The apparatus according to claim 1, wherein said heat collecting device further includes a first vacuum device surrounding said heat collecting portion, and a second vacuum device surrounding said first vacuum device, each of said first and second vacuum devices having a light-transmissive wall corresponding to said heat collecting portion.

3. The apparatus according to claim 1, wherein said thermoelectric generator device includes a thermoelectric element and a heat-dissipating member, said thermoelectric element having a heat-collecting side in intimate contact with said heat conducting portion, and a heat-radiating side opposite to said heat-collecting side and in intimate contact with said heat-dissipating member.

4. The apparatus according to claim 1, wherein said water storage unit further includes a water tower and an electrically controlled valve connected between said water tank and said water tower, said electrically controlled valve being connected electrically to said control unit.

5. The apparatus according to claim 1, wherein each of said honeycomb type water screen and said moisture absorbing screen is a fabric.

6. The apparatus according to claim 1, wherein said control unit effects the rise and drop in the temperature of said first temperature face by changing polarities of electricity supplied to said thermoelectric cooling unit by said thermoelectric generator device.

7. A method for thermoelectrically generating cool/warm air, comprising:
(A) collecting heat energy;
(B) converting the heat energy to an electric energy output;
(C) supplying the electric energy output in step (B) to a thermoelectric cooling unit;
(D) causing water in a water tank to reach a desired temperature through the thermoelectric cooling unit;
(E) causing the water in the water tank to be distributed across a honeycomb type water screen;
(F) blowing air toward the honeycomb type water screen so as to generate an air current with a desired temperature; and
(G) passing the air current through a moisture absorbing screen such that the air current has a lowered moisture content, thereby resulting in an output of cool/warm air.
